(19) United States
(12) Patent Application Publication
(10) Pub. No.: US 2024/0159949 A1
(43) Pub. Date: May 16, 2024

(54) OPTICAL FILTER

(71) Applicant: VisEra Technologies Company Limited, Hsin-Chu City (TW)

(72) Inventors: Wen-Yu SHIH, Hsin-Chu City (TW); Lai-Hung LAI, Hsin-Chu City (TW)

(21) Appl. No.: 18/326,428

(22) Filed: May 31, 2023

Related U.S. Application Data
(60) Provisional application No. 63/425,812, filed on Nov. 16, 2022.

(51) Int. Cl. G02B 5/20; G02B 5/00; H10K 30/80

(52) U.S. Cl. CPC G02B 5/208; G02B 5/008; H10K 30/80

(57) ABSTRACT

An optical filter includes a substrate and a filtering stack disposed on the substrate. The filtering stack includes first layers and second layers, wherein the first layers and the second layers are alternately arranged. The second layers include a plasmonic transparent conducting film (TCF), wherein the plasmonic transparent conducting film is made of non-stoichiometric compounds.

### CROSS REFERENCE TO RELATED APPLICATIONS

This application claims the benefit of U.S. Provisional Application No. 63/425,812, filed Nov. 16, 2022, the entirety of which is incorporated by reference herein.

### BACKGROUND OF THE INVENTION

### Field of the Invention

The present disclosure relates to an optical filter, and, in particular, to the filtering stack of an optical filter.

### Description of the Related Art

Electronic devices such as laptop computers, cellular telephones, and other equipment are sometimes provided with light sensors. For example, optical filters may be incorporated into a device to provide necessary information about the surrounding lighting conditions. The optical readings of the optical filters may be used to control the device settings. For example, if bright daylight conditions are detected, the electronic device may increase the display brightness to compensate. In some configurations, the optical filters are implemented to gather information about the colors of the ambient light (such as the spectrum). The colors of a displayed image can be adjusted based on the colors of the ambient light.

In order to gather optical readings on different colors, the optical filters may include narrow band pass filters (NBPF), which are multi-film elements arranged on a substrate. Each of the narrow band pass filters may allow a specific wavelength range or wave band (such as spectral range of color) of the incident light to transmit, while other unwanted wavelength range are suppressed (for example, the unwanted wavelength range is either absorbed or reflected away by the narrow band pass filters), thereby elevating the ability to distinguish color. The transmitted wavelength range and the suppressed wavelength range are also known as a passband and a cutband, respectively. Conventionally, the multi-film elements include alternately stacked low refractive index layers and high refractive index layers. In order to suppress longer wavelengths, the multi-film stack may need to be designed with a higher quantity of alternating layers, thus leading to a higher thickness. Therefore, these and related issues need to be addressed through the design and manufacture of the optical filter.

### BRIEF SUMMARY OF THE INVENTION

An embodiment of the present invention provides an optical filter, the optical filter includes a substrate and a filtering stack disposed on the substrate. The filtering stack includes first layers and second layers, wherein the first layers and the second layers are alternately arranged. The second layers include a plasmonic transparent conducting film (TCF), wherein the plasmonic transparent conducting film is made of non-stoichiometric compounds.

### BRIEF DESCRIPTION OF THE DRAWINGS

The present invention can be more fully understood by reading the subsequent detailed description and examples with references made to the accompanying drawings, wherein:

FIG. 1 is a schematic diagram of an optical filter, according to a comparative example.

FIGS. 2A-2E are plots of the optical filter with various characteristics, according to the comparative example.

FIG. 3 is a schematic diagram of an optical filter, according to some embodiments of the present disclosure.

FIG. 4 is a cross-sectional view of the optical filter, according to some embodiments of the present disclosure.

FIGS. 5A-5D are plots of a transparent conducting film with various characteristics, according to some embodiments of the present disclosure.

FIGS. 6A-6D are plots of the optical filter with various characteristics, according to some embodiments of the present disclosure.

FIG. 7 is a schematic diagram of band gap energy, according to some embodiments of the present disclosure.

FIG. 8 is a cross-sectional view of an optical filter, according to other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to de scribe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean±20% of the stated value, more typically ±10% of the stated value, more typically ±5% of the stated value, more typically ±3% of the stated value, more typically ±2% of the stated value, more typically ±1% of the stated value and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In nature, ambient light may be a combination of various colors of all wavelengths. In an optical filter with a narrow band pass configuration, a narrow band pass filter (NBPF) may be a specialized optical filter designed to isolate a narrow wavelength range while rejecting all other optical wavelengths. In some embodiments, the narrow band pass filter may be designed to control full width at half maximum (FWHM), transmittance, reflectance, central wavelength (CWL), and other parameters. For example, the full width at half maximum is the width of a passband curve measured between the two points on the transmittance axis, which are half the maximum amplitude. The transmittance is the ratio of the transmitting light to the incident light of the specimens, and the reflectance the ratio of the reflecting light to the incident light of the specimens. The central wavelength is the weighted average of wavelengths across the passband curve. The aforementioned parameters may determine the overall optical performance of the optical filter.

A conventional narrow band pass filter may include a filtering stack, which includes low refractive index layers and high refractive index layers that are alternately arranged. By creating a large enough difference between low refractive index and high refractive index, an interference may be generated to suppress unwanted wavelengths of the ambient light. The narrow band pass filter can be applied in the auto-drive industry, which significantly improves the driving issues, for example, under adverse weather conditions. However, under longer wavelength of the incident light, the difference between refractive indices is inadequate to generate the necessary interference. To compensate the insufficient difference between refractive indices, the filtering stack may need to incorporate additional low refractive index layers and high refractive index layers to constitute sufficient reflectivity for the suppression of the longer wavelength. As a result, the filtering stack becomes too thick, in which the manufacturing cost increases. Moreover, the stress of the overall filtering stack would become too high, causing more structural defects. The device scaling may also be more challenging due to larger dimension.

The present disclosure incorporates a transparent conducting film (TCF) to serve as the low refractive index layer of the optical filter (such as the narrow band pass filter), which has a passband partially overlapped with the wavelength range between 800 nm and 1700 nm. Such wavelength range embodies the wavelength range of near infrared (NIR) and the wavelength range of short wave infrared (SWIR), thus the optical filter can be effectively applied for near infrared and short wave infrared. It should be appreciated that near infrared operates in the wavelength range between 800 nm and 1000 nm, while the short wave infrared operates in the wavelength range between 1100 nm and 1800 nm. In order to clearly see the targets inside or outside the vehicle, the utilization of infrared is required.

The advantage of using short wave infrared is to be able to see the objects under any weather or luminance conditions. Moreover, short wave infrared can determine any potentially dangerous road conditions (such as icing). This is because short wave infrared can inspect unique spectrum determined by the chemical or physical characteristics of every material. In the wavelength of 1550 nm, short wave infrared may completely transmit through water, which allows users to see through fog, cloud, smoke, or vapor. An apparatus with such wavelength may be designed with further distance inspection and higher sensitivity, allowing aircrafts to fly through clouds or to navigate through adverse weather condition.

The transparent conducting film of the present application may include non-stoichiometric compounds that exhibit plasmonic feature. The inventor has discovered that the plasmonic transparent conducting film can have lower refractive index than that of the conventional materials used, thereby creating a larger difference between refractive indices under longer wavelength. Nevertheless, in larger part, the plasmonic transparent conducting film itself may absorb the incident light under longer wavelength, while the conventional narrow band gap material may still be used to absorb the incident light under shorter wavelength (such as visible light). Therefore, the conventional narrow band pass filter of interference type can be evolved into the innovative narrow band pass filter of absorption type. Using materials with absorption spectrum, the absorption type narrow band pass filter is able to filter the undesired wavelengths of the incident light, and to allow the desired wavelengths of the incident light to transmit. In the innovative narrow band pass filter, the filtering stack is able to maintain at an acceptable thickness, and the unwanted wavelengths (such as longer wavelength) may still be effectively suppressed.

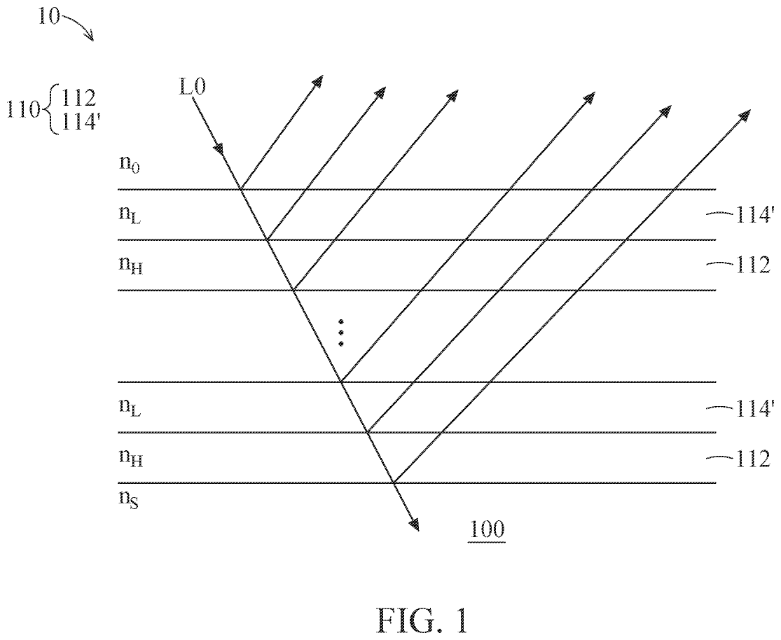

FIG. 1 is a schematic diagram of an optical filter 10, according to a comparative example. According to the comparative example, the optical filter 10 may include a substrate 100 and a filtering stack 110. The filtering stack 110 may include first layers 112 and second layers 114′. The first layers 112 and the second layers 114′ are the high refractive index layers and the low refractive index layers, respectively. Additionally, an incident light L0 may be irradiated from ambient air, and may be transmitted into the filtering stack 110. It should be appreciated that a refractive index no of ambient air is 1.

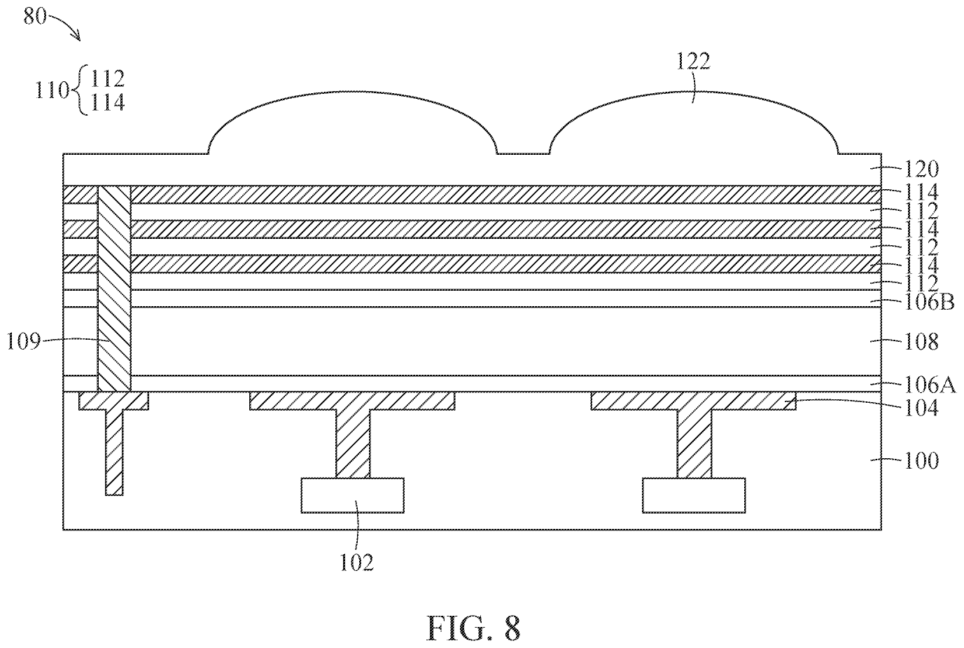

Referring to FIG. 1, the substrate 100 may be, for example, a wafer or a chip, but the present disclosure is not limited thereto. In some embodiments, the substrate 100 may be a semiconductor substrate, for example, silicon (Si) substrate. Furthermore, in some embodiments, the semiconductor substrate may also be an elemental semiconductor (such as germanium (Ge)), a compound semiconductor (such as gallium nitride (GaN), silicon carbide (SiC), gallium arsenide (GaAs), gallium phosphide (GaP), indium phosphide (InP), indium arsenide (InAs), or indium antimonide (InSb)), an alloy semiconductor (such as silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, or gallium indium arsenic phosphide (GaInAsP) alloy), or a combination thereof. In some embodiments, the substrate 100 may be a photoelectric conversion substrate, such as a silicon substrate or an organic photoelectric conversion layer (to be described with more details in reference with FIG. 8).

In other embodiments, the substrate 100 may also be a semiconductor on insulator (SOI) substrate. The semiconductor on insulator substrate may include a base plate, a buried oxide layer disposed on the base plate, and a semiconductor layer disposed on the buried oxide layer. Furthermore, the substrate 100 may be an n-type or a p-type conductive type.

In some embodiments, the substrate 100 may include various p-type doped regions and/or n-type doped regions (not shown) formed by, for example, an ion implantation and/or a diffusion process. In some embodiments, transistors, photodiodes, or the like, may be formed at the active regions, which are defined by an isolation structure.

In some embodiments, the isolation structure may be embedded within the substrate 100 to define active regions and to electrically isolate active region elements within or above the substrate 100, but the present disclosure is not limited thereto. The isolation structure may be deep trench isolation (DTI) structure, shallow trench isolation (STI) structure, and local oxidation of silicon (LOCOS) structure. In some embodiments, the formation of the isolation structure may include, for example, forming an insulating layer on the substrate 100. Through a suitable photolithography process and a suitable etching process, trenches may be formed extending into the substrate 100.

Next, a liner of rich nitrogen-containing materials (such as silicon oxynitride (SiON)) may be grown conformally along the trenches. After that, insulating materials (such as silicon dioxide (SiO₂), silicon nitride (SiN), or silicon oxynitride) may be filled into the trenches by a suitable deposition process. An annealing process may then be performed on the insulating materials in the trenches, followed by a planarization process, such as chemical mechanical polish (CMP), on the substrate 100 to remove excessive insulating materials, so the insulating materials in the trenches are level with the top surface of the substrate 100.

A refractive index nₛ of the substrate 100 is between 1.5 and 5.7 at the wavelength of 550 nm. The refractive index is a characteristic of a substance that changes the speed of light, and it is a value obtained by dividing the speed of light in vacuum by the speed of light in the substance. When light travels between two different materials at an angle, its refractive index determines the angle of light transmission (refraction). In addition to the refraction index, another critical optical constant being discussed is the extinction coefficient. The extinction coefficient is a characteristic that determines how strongly the substance absorbs or reflects radiation or light at a particular wavelength. For example, when the substrate 100 is made of glass, the extinction coefficient of the substrate 100 at the wavelengths of visible light can reach 0, due to the material's transparency. The optical constants (for example, the refractive index and the extinction coefficient) may vary under different optical wavelength of the incident light being irradiated.

When the incident light is being irradiated onto the substance, there would be three interactions. The first interaction is reflection, in which a portion of the incident light is reflected away at the surface of the substance. The second interaction is absorption, in which another portion of the incident light is propagated into and absorbed by the substance. The third interaction is transmittance, in which the remaining portion of the incident light has passed through the substance. The optical constants (for example, the refractive index and the extinction coefficient) of the mediums can determine how will the incident light reflect, absorb, and transmit from one medium into another medium. The following equations calculate the behavior of the incident light traveling from medium A to medium B:

$${N}_{A} = {n}_{A} + i {κ}_{A} ; {N}_{B} = {n}_{B} + i {κ}_{B} \qquad ( 1 )$$

$$R = {\vert \frac{{N}_{A} - {N}_{B}}{{N}_{A} + {N}_{B}} \vert}^{2} \qquad ( 2 )$$

$$A = ( 1 - R ) \times {e}^{\frac{4 πκ d}{λ}} \qquad ( 3 )$$

$$T = 1 - R - A \qquad ( 4 )$$

In equation (1), n_{A} and n_{B} are refractive indices of medium A and medium B, respectively. Moreover, κ_{A} and κ_{B} are extinction coefficients of medium A and medium B, respectively. The calculated N_{A} and N_{B} are optical properties that can be described by a complex index of refraction of medium A and medium B, respectively. In equation (2), R is the reflectivity at the interface between medium A and medium B. The reflectivity is determined by n_{A}, n_{B}, κ_{A}, and κ_{B}. In equation (3), A is the absorptivity of the substance. Since the incident light is propagated into medium B, equation (3) calculates the absorptivity of medium B. Additionally, κ is the extinction coefficient of the substance (in this case, medium B), d is the thickness of the substance, and λ is the optical wavelength of the incident light. In equation (4), T is the transmittance of the substance (or medium B). It should be understood that, based on the principle of energy conservation, the sum of the reflectivity, the absorptivity, and the transmittance of the incident light should always be 1 (or 100% of the optical energy of the incident light).

Still referring to FIG. 1, the filtering stack 110 may be disposed on the substrate 100. In some embodiments, the filtering stack 110 includes first layers 112 and second layers 114′ that are alternately arranged. According to the comparative example, the filtering stack 110 may allow a desired wavelength of the incident light L0 to transmit, and other unwanted wavelengths of the incident light L0 may be suppressed. From another perspective, the filtering stack 110 may be a set of layers, while the first layers 112 and the second layers 114′ may be a first subset of layers and a second subset of layers, respectively. As mentioned previously, the first layers 112 may be high refractive index layers, and the second layers 114′ may be low refractive index layers. The thickness of the first layers 112 may be between 10 nm and 1 μm, while the thickness of the second layers 114′ may be between 10 nm and 1 μm. The quantity of alternating first layers 112 and second layers 114′ may be any positive integer, depending on the application and the design requirements.

As mentioned previously, the transmitted portion may be considered as the passband of the incident light L0, while the reflected portion and the absorbed portion (without transmission) may be considered as the cutband of the incident light L0. In a specific example, the first layers 112 and the second layers 114′ may be made of silicon hydride (SiH) and silicon dioxide, respectively. The filtering stack 110 may be deposited on the substrate 100 using a suitable deposition process, such as physical vapor deposition (PVD), chemical vapor deposition (CVD), high-density plasma chemical vapor deposition (HDP-CVD), plasma-enhanced chemical vapor deposition (PECVD), flowable chemical vapor deposition (FCVD), sub-atmospheric chemical vapor deposition (SACVD), the like, or a combination thereof.

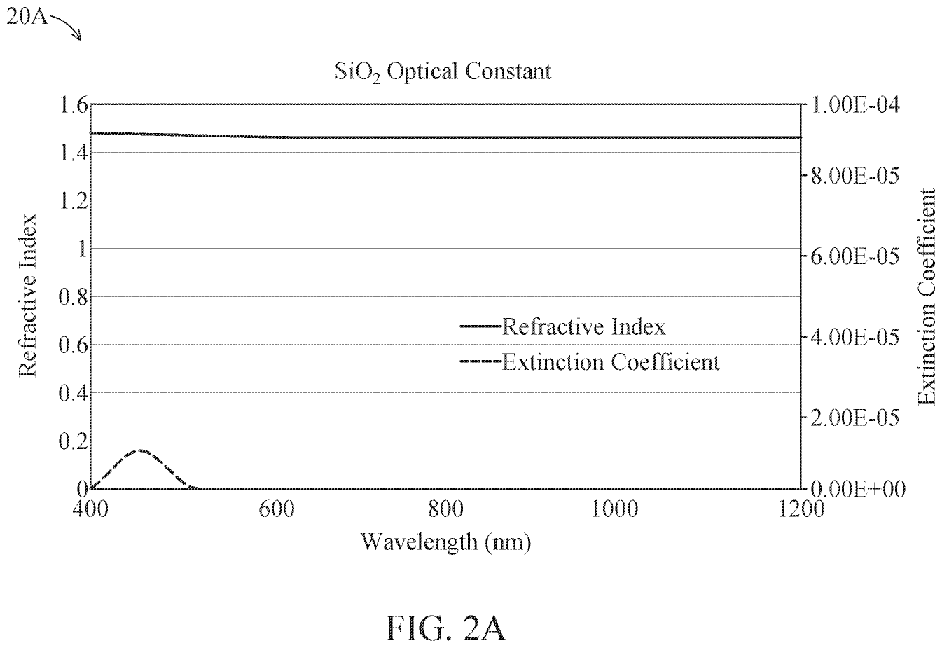

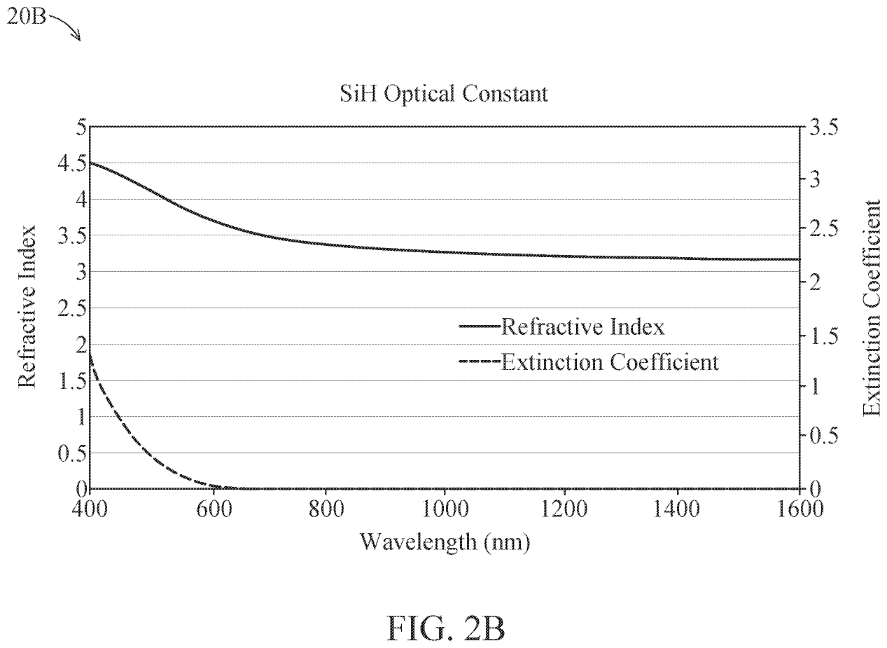

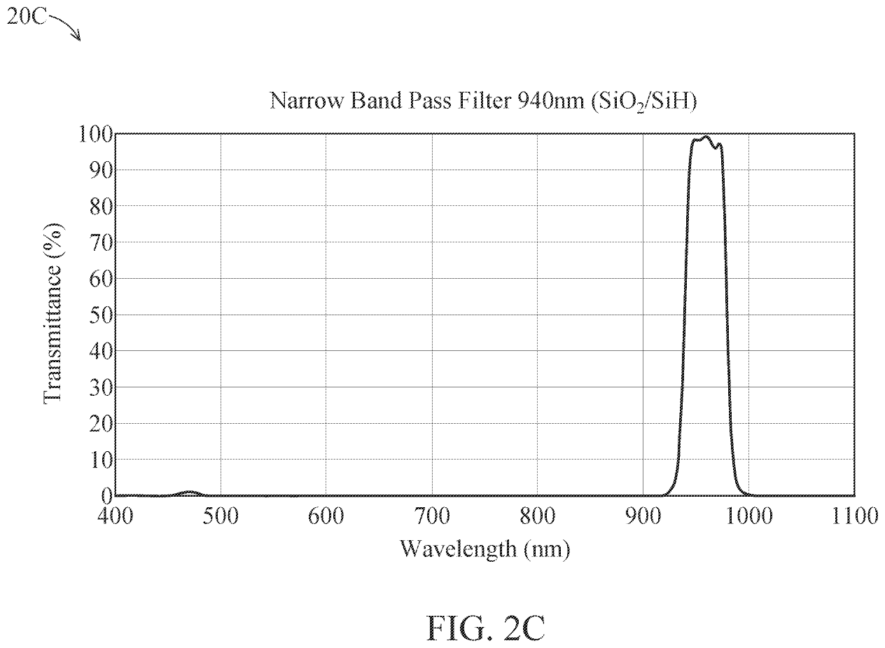

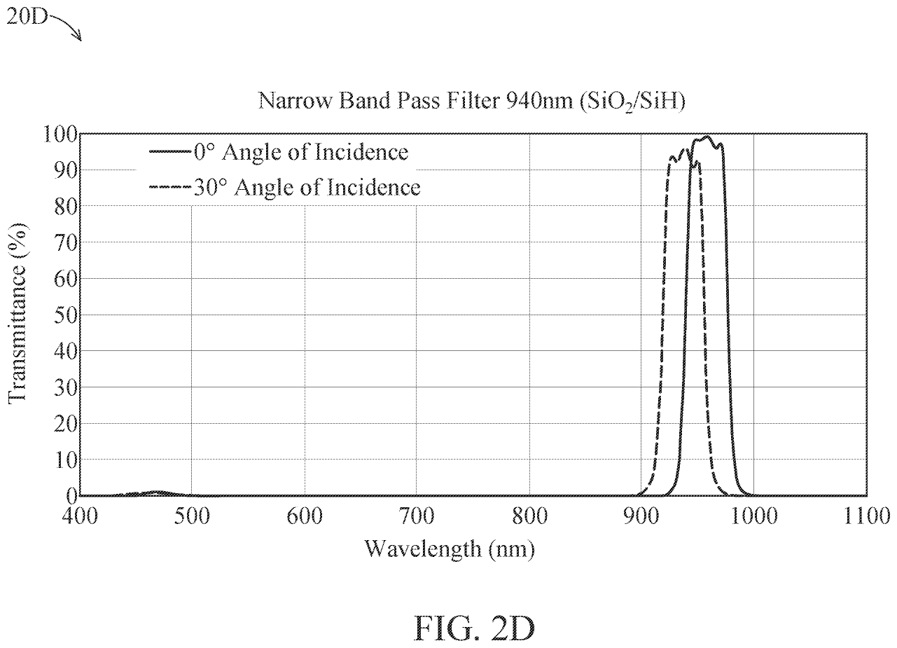

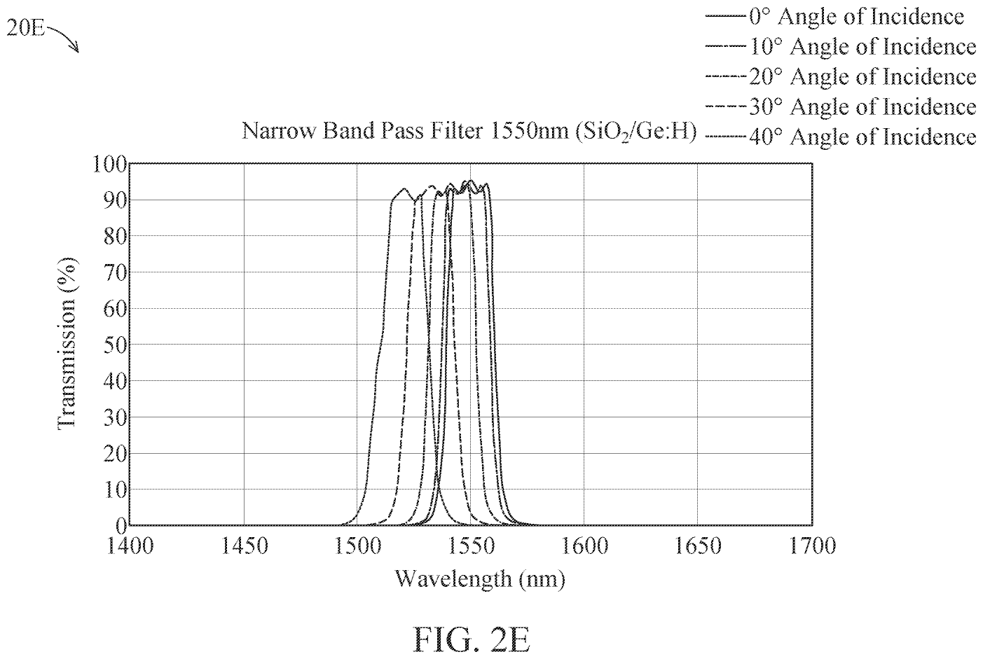

FIGS. 2A-2E are plots 20A-20E of the optical filter 10 with various characteristics, according to the comparative example. The plots 20A-20E are based on the schematic diagram shown in FIG. 1. As mentioned previously, the optical filter 10 is the interference type narrow band pass filter. Specifically, the high refractive index layers and the low refractive index layers are made of silicon hydride and silicon dioxide, respectively.

Referring to FIG. 2A, the plot 20A is illustrated. The plot 20A describes the optical constants (for example, the refractive index and the extinction coefficient) of silicon dioxide under different optical wavelength of the incident light L0. The refractive index of silicon dioxide remains substantially constant from short wavelength to long wavelength. For example, the refractive index of silicon dioxide at 940 nm is 1.46. The extinction coefficient of silicon dioxide remains close to 0 from short wavelength to long wavelength.

Referring to FIG. 2B, the plot 20B is illustrated. The plot 20B describes the optical constants (for example, the refractive index and the extinction coefficient) of silicon hydride under different optical wavelength of the incident light L0. The refractive index of silicon hydride reaches near 4.5 at the optical wavelength of 400 nm. As the optical wavelength increases, the refractive index of silicon hydride gradually decreases. It can also be noticed that the refractive index becomes substantially constant as the optical wavelength increases beyond approximately 1100 nm. For example, the refractive index of the silicon hydride is 3.3 at 940 nm. The extinction coefficient of silicon hydride is between 1 and 1.5 at the optical wavelength of 400 nm. As the optical wavelength increases, the extinction coefficient of silicon hydride gradually decreases. The extinction coefficient approaches close to 0 as the optical wavelength increase beyond 600 nm.

As mentioned previously, the interference type narrow band pass filter mainly depends on the difference between refractive indices. Plot 20A illustrated that the refractive index of silicon dioxide used in the low refractive index layers remains constant from short wavelength to long wavelength. Therefore, it is crucial for the refractive index of silicon hydride used in the high refractive index layers to create the difference between refractive indices in order to generate the necessary interference. However, as the optical wavelength increases, the refractive index of silicon hydride gradually decreases and remains substantially constant. As the result, the difference between refractive indices is inadequate in longer wavelength to generate the required interference. It would therefore require a larger quantity of alternating low refractive index layers and high refractive index layers to achieve the required interference. Alternatively, it may be necessary to seek out other materials with a larger difference between refractive indices, while these materials are usually rare and less accessible.

Referring to FIG. 2C, the plot 20C is illustrated. The plot 20C describes the transmittance of the optical filter 10 (such as the narrow band pass filter) at the wavelength of 940 nm. As mentioned previously, the wavelength of 940 nm is ideal for near infrared, which can be absorbed by water. The interference of the narrow band pass filter can be calculated using the relative wavenumber shown in the following equation:

$$Δ g = \frac{2}{π} {sin}^{- 1} \vert \frac{1 - \frac{{n}_{H}}{{n}_{L}}}{1 + \frac{{n}_{H}}{{n}_{L}}} \vert \qquad ( 5 )$$

In equation (5), Δg is the relative wavenumber, which is the inverse of the optical wavelength. As mentioned previously, n_{H} and n_{L} are the refractive indices of silicon hydride and silicon dioxide, respectively. As the difference between refractive indices increases, the ratio of n_{H} to n_{L} would also increase. The relative wavenumber increases with increasing ratio of n_{H} to n_{L}. The details of the filtering stack 110 of the optical filter 10 (for example, the narrow band pass filter at the wavelength of 940 nm) are summarized in Table 1.

TABLE 1

| | | |
|---|---|---|
| Layer | Material | Thickness |

Air

| | | | |
|---|---|---|---|
| 1 | silicon dioxide (SiO₂) | 72.70 | nm |
| 2 | silicon hydride (SiH) | 24.45 | nm |
| 3 | silicon dioxide (SiO₂) | 109.49 | nm |
| 4 | silicon hydride (SiH) | 41.74 | nm |
| 5 | silicon dioxide (SiO₂) | 84.90 | nm |
| 6 | silicon hydride (SiH) | 33.57 | nm |
| 7 | silicon dioxide (SiO₂) | 151.56 | nm |
| 8 | silicon hydride (SiH) | 28.74 | nm |
| 9 | silicon dioxide (SiO₂) | 59.21 | nm |
| 10 | silicon hydride (SiH) | 43.70 | nm |
| 11 | silicon dioxide (SiO₂) | 146.97 | nm |
| 12 | silicon hydride (SiH) | 69.18 | nm |
| 13 | silicon dioxide (SiO₂) | 163.79 | nm |
| 14 | silicon hydride (SiH) | 138.37 | nm |
| 15 | silicon dioxide (SiO₂) | 163.79 | nm |
| 16 | silicon hydride (SiH) | 69.18 | nm |
| 17 | silicon dioxide (SiO₂) | 163.79 | nm |
| 18 | silicon hydride (SiH) | 69.18 | nm |
| 19 | silicon dioxide (SiO₂) | 163.79 | nm |
| 20 | silicon hydride (SiH) | 138.37 | nm |
| 21 | silicon dioxide (SiO₂) | 163.79 | nm |
| 22 | silicon hydride (SiH) | 69.18 | nm |
| 23 | silicon dioxide (SiO₂) | 163.79 | nm |
| 24 | silicon hydride (SiH) | 69.18 | nm |
| 25 | silicon dioxide (SiO₂) | 163.79 | nm |
| 26 | silicon hydride (SiH) | 138.37 | nm |
| 27 | silicon dioxide (SiO₂) | 163.79 | nm |
| 28 | silicon hydride (SiH) | 69.18 | nm |
| 29 | silicon dioxide (SiO₂) | 20.00 | nm |

Substrate (glass)

| | | |
|---|---|---|
| Total | 2957.54 | nm |

As shown in Table 1, the thickness of the filtering stack 110 is 2957.54 nm, which is nearly 3 μm. It should be appreciated that the layers in the filtering stack 110 are listed from top to bottom. For example, layer 1 is the topmost layer, in which the upper surface thereof is exposed to ambient air. In contrast, layer 29 is the bottommost layer that is in contact with the substrate 100. As mentioned previously, fabricating the filtering stack 110 of nearly 3 μm may consume a very high manufacturing cost, and the device scaling may become more difficult. Furthermore, the cycle time to prepare the optical filter 10 with such filtering stack 110 increases, thus the wafer per hour (WPH) of the production line may be lowered. Since the filtering stack 110 has a relatively high thickness, the overall stress would increase, causing more structural defects.

Referring to FIG. 2D, the plot 20D is illustrated. The plot 20D compares the angles of incidence (AOI) of the incident light L0 at 0° and at 30°. A difference between the central wavelength of the passband of the incident light L0 at the angle of incidence of 0° and the central wavelength of the passband of the incident light L0 at the angle of incidence of 30° is larger than 20 nm. However, due to the blue shift property occurred at a large angle of incidence, there will be a color-shift phenomenon. As it can be seen, when the angle of incidence changes from 0° to 30°, the major shift occurred in the region of the transmittance less than 50%. It indicates that there is less near infrared light entering into the sensor.

Referring to FIG. 2E, the plot 20E is illustrated. The plot 20E describes the optical filter 10 (such as the narrow band pass filter) at the wavelength of 1550 nm. For the narrow band pass filter at the wavelength of 1550 nm, the thickness of the filtering stack 110 may be between 5.3 μm and 5.9 μm. Additionally, the angles of incidence of the incident light L0 at 0°, 10°, 20°, 30°, and 40° are being compared. For example, when the incident light L0 is inclined from 0° to 30°, the passband of the narrow band pass filter at the wavelength of 1550 nm may be blue shifted between 30 nm and 40 nm. In other words, a difference between the central wavelength of the passband of the incident light L0 at the angle of incidence of 0° and the central wavelength of the passband of the incident light L0 at the angle of incidence of 30° is 30 nm to 40 nm. When the angle of incidence changes from 0° to 30°, the major shift occurred in the region of the transmittance less than 50%. It indicates that there is less near infrared light entering into the sensor.

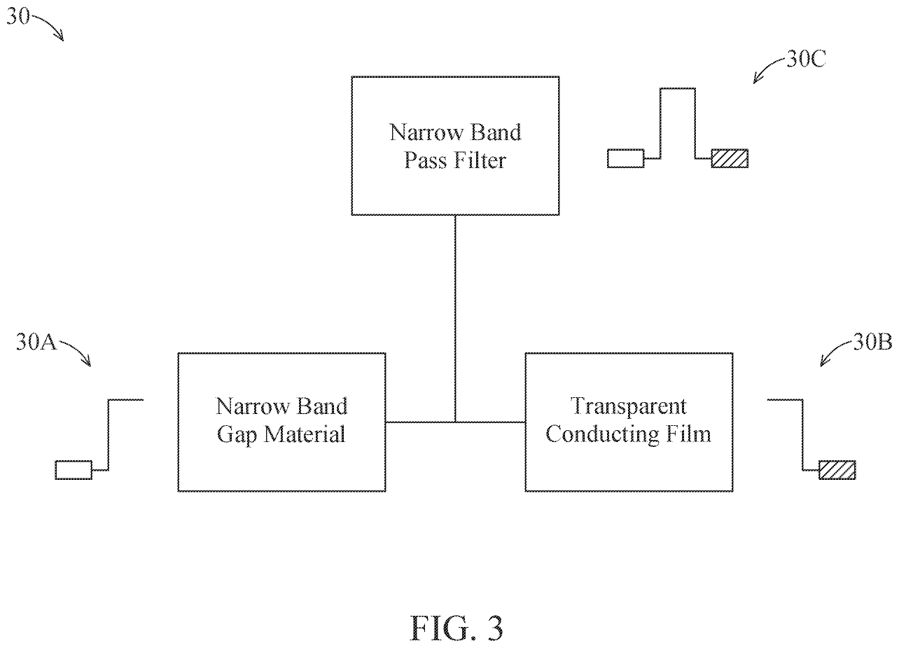

FIG. 3 is a schematic diagram of an optical filter 30, according to some embodiments of the present disclosure. In comparison with the optical filter 10 in FIG. 1, the optical filter 30 incorporates the transparent conducting film to replace the conventional silicon dioxide. Furthermore, the optical filter 10 may be the interference type, while the optical filter 30 may be the absorption type. The schematic diagram illustrates a long pass filter (LPF) 30A, a short pass filter (SPF) 30B, and a narrow band pass filter 30C.

Referring to FIG. 3, the long pass filter 30A and the short pass filter 30B may be combined to produce the narrow band pass filter 30C. It should be understood that the long pass filter 30A may allow the long wavelength of the incident light to transmit, while the short wavelength of the incident light may be suppressed. In the present embodiment, the short wavelength of the incident light may be absorbed by the narrow band gap materials. The short wavelength may be the wavelength of the visible light. Moreover, the short pass filter 30B may allow the short wavelength of the incident light to transmit, while the long wavelength of the incident light may be suppressed. In the present embodiment, the long wavelength of the incident light may be absorbed by the transparent conducting film. The long wavelength may be the wavelength of near infrared or short wave infrared, depending on the designated wavelength of the resulting narrow band pass filter 30C.

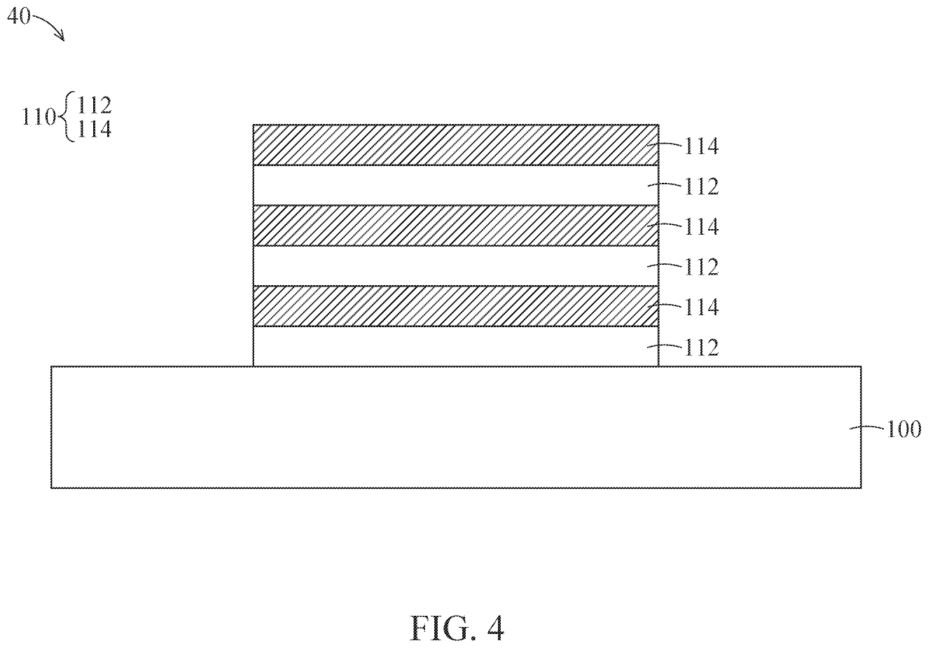

FIG. 4 is a cross-sectional view of the optical filter 40, according to some embodiments of the present disclosure. In comparison with the optical filter 10 in FIG. 1, the optical filter 40 replaces the second layers 114′ of silicon dioxide with second layers 114 of the plasmonic transparent conducting film. The features of the substrate 100 and filtering stack 110 are similar to those illustrated in FIG. 1, and the details are not described again herein to avoid repetition.

Referring to FIG. 4, the filtering stack 110 may include the first layers 112 and the second layers 114. Even though FIG. 4 illustrates three first layers 112 and three second layers 114 alternately arranged, but the present disclosure is not limited thereto. For example, the filtering stack 110 may have a higher or lower quantity of alternating first layers 112 and second layers 114. Furthermore, the arrangement of the first layers 112 and the second layers 114 may also vary. For example, from top to bottom of the filtering stack 110, the first layers 112 and the second layers 114 may be arranged in a (T−N)^{L}−T order, a (T−N)^{L} order, an N−(T−N)^{L} order, or an (N−T)^{L} order, wherein N represents the first layers 112, T represents the second layers 114, and L represents the quantity of alternating first layers 112 and second layers 114. In some embodiments, L is between 15 and 30. More specifically, the topmost layer and the bottommost layer of the filtering stack 110 may respectively both be first layers 112, they may respectively both be second layers 114, they may respectively be the first layer 112 and the second layer 114, or they may respectively be the second layer 114 and the first layer 112.

In some embodiments, the thickness of the first layers 112 may be between 10 nm and 1 μm. The first layers 112 may include narrow band gap materials, such as copper zinc tin sulfide (Cu₂ZnSnS₄, CZTS), copper strontium tin sulfide (Cu₂SrSnS₄, CSTS), copper indium gallium selenide (CuIn₁₋ₓGaₓSe₂, CIGS), amorphous silicon, silicon hydride (SiH), silicon germanium (SiGe), germanium hydride (GeH), germanium peroxide (GeOH), silicon tin (SiSn), germanium silicon tin (GeSiSn), or germanium tin (GeSn), the like, or a combination thereof. The band gap energy of the narrow band gap materials may be between 1.37 eV and 2 eV. For example, silicon hydride has the band gap energy of 2.0 eV, copper strontium tin sulfide has the band gap energy of 1.98 eV, copper zinc tin sulfide has the band gap energy of 1.50 eV, copper indium gallium selenide has the band gap energy of 1.37 eV, silicon germanium and germanium hydride have the band gap energy of 1.1 eV, and silicon tin, germanium silicon tin, and germanium tin have the band gap energy less than 1 eV. Generally, any materials with the band gap energy less than 2 eV may be used to absorb the short wavelength of the incident light. In the wavelength range between 300 nm and 600 nm, the extinction coefficient of the narrow band gap material is greater than 0.01, greater than 0.05, or greater than 0.1. The first layers 112 may be formed by any suitable deposition process mentioned above.

In some embodiments, the thickness of the second layers 114 may be between 10 nm and 1 μm. The second layers 114 may include plasmonic transparent conducting film, which may be a plasmonic transparent conducting oxide (TCO). The plasmonic transparent conducting oxide may be a binary or a ternary compound with one or two metallic elements. Examples of the transparent conducting oxide may include indium (III) oxide (In₂O₃), zinc oxide (ZnO), indium (III) oxide-zinc oxide, aluminum-doped zinc oxide (AZO), gallium zinc oxide (GZO), indium tin oxide (ITO), indium zinc oxide (IZO), indium tungsten oxide (IWO), magnesium-doped zinc oxide (MZO), antimony tin oxide (ATO), fluorine-doped tin oxide (FTO), indium gallium tin oxide (IGTO), tin (IV) oxide (SnO₂), titanium-doped niobium oxide (TNO), titanium nitride (TiN), copper (I) oxide (Cu₂O), tantalum oxide (Ta₂Oₓ), gallium indium oxide (GaInOₓ), indium gallium zinc oxide (InGaZnO), zinc tin oxide (ZnₓSnO_{y}), zinc gallium oxide (ZnGaₓ O_{y}), gallium indium oxide (GaInOₓ), zinc indium oxide (Znₓ In_{y}O_{z}), vanadium oxide (VOₓ), molybdenum oxide (MoOₓ), the like, or a combination thereof. The second layers 114 may be formed by sputtering, atomic layer deposition (ALD), evaporation, chemical vapor deposition, magnetron sputtering, pulsed layer deposition, so-gel process, spin-on coating, solvothermal method, aqueous solution deposition, the like, or a combination thereof. Any of the deposition method can be adjusted to obtain the desired optical constants (for example, the refractive index and the extinction coefficient) of the transparent conducting oxide. For the absorption type narrow band pass filter, the narrow band gap material is transparent at the wavelengths of near infrared and short wave infrared, while the plasmonic transparent conducting film is absorptive at the wavelengths of near infrared and short wave infrared.

In some embodiments, the transparent conducting oxides are metal oxides with high optical transmittance and high electrical conductivity. The metal oxides have high optical transmittance at the wavelength of visible light (between 400 nm and 700 nm). The electrical conductivity of the metal oxides can be close to that of metals, which can often be induced by doping with other elements. The transparent conducting oxides may also be referred to as wide band gap oxide semiconductors, with the band gap energy larger than 3.2 eV. The band gap energy may overlap with the ultraviolet wavelength, where no visible light can be absorbed, which allows the transparent conducting oxides to appear transparent to the human eyes. Moreover, the transparent conducting oxides may also reflect the wavelengths of near infrared and infrared (such as heat).

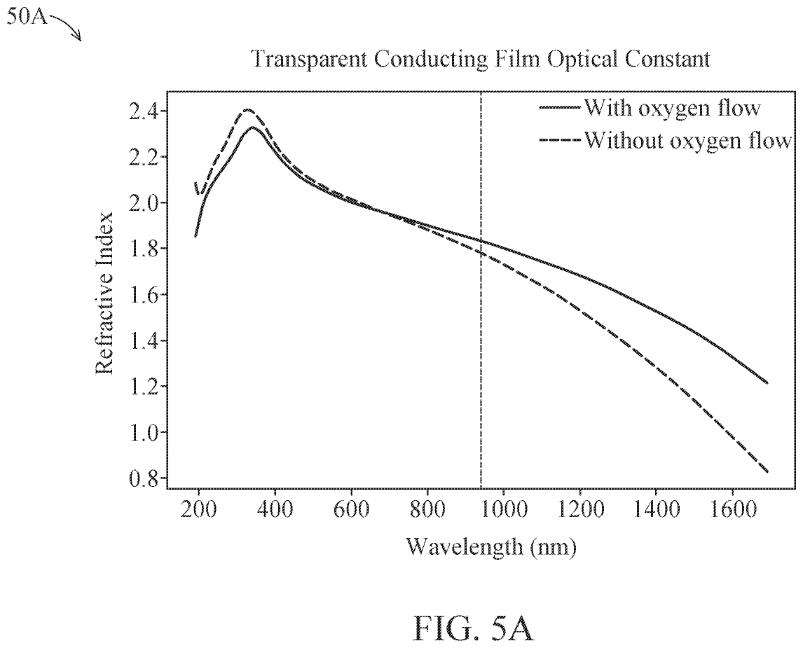

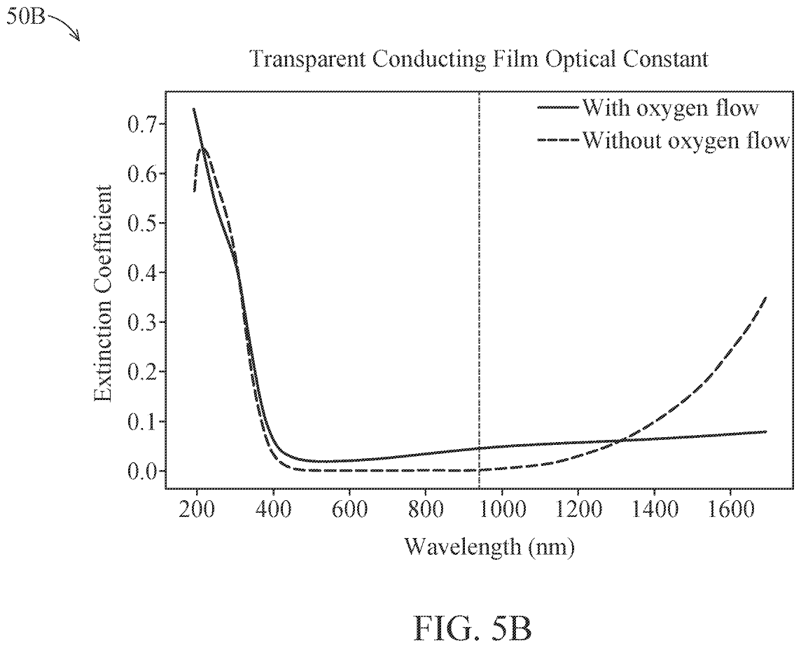

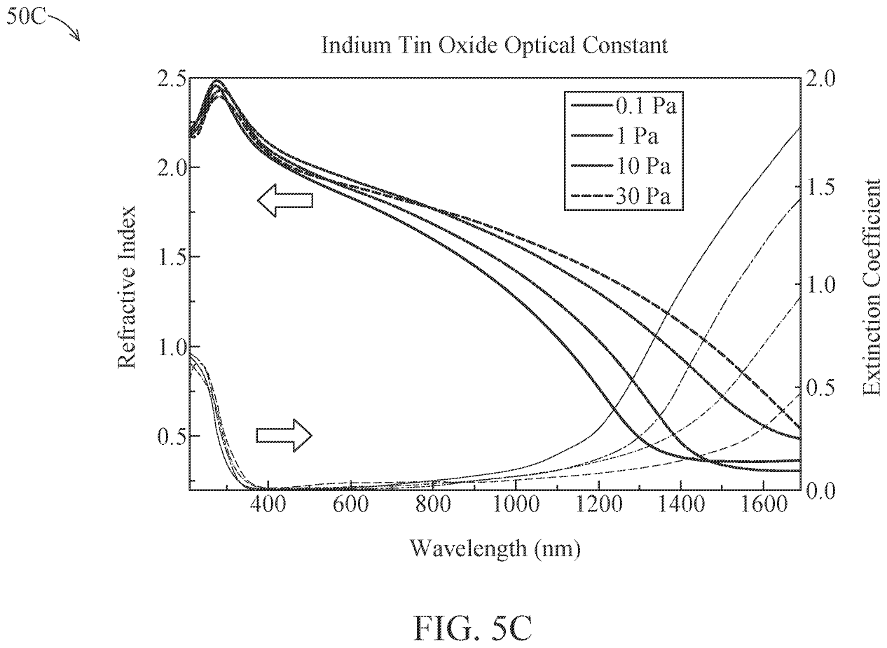

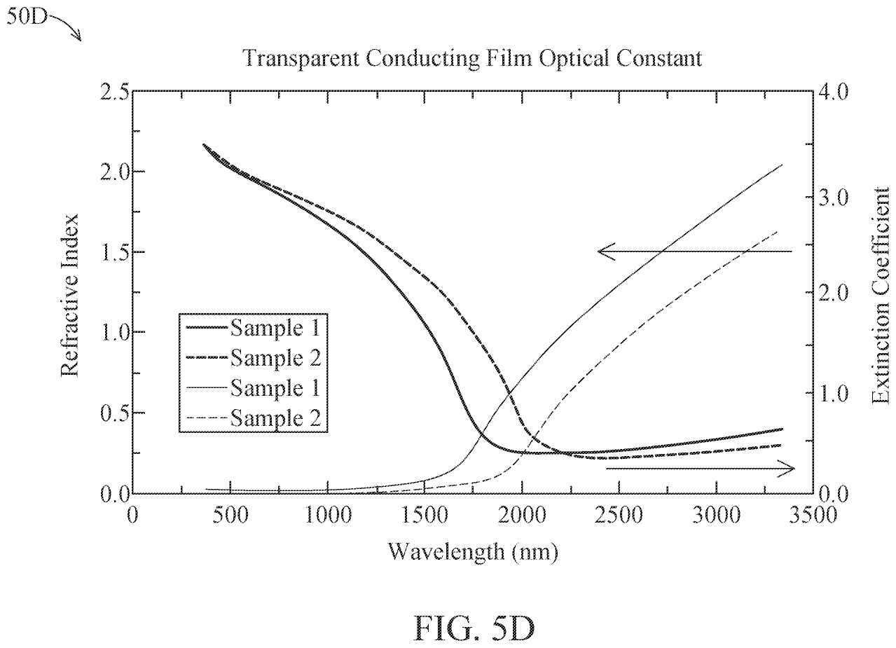

FIGS. 5A-5D are plots 50A-50D of a transparent conducting film with various characteristics, according to some embodiments of the present disclosure. The plots 50A-50D provides a more in-depth discussion regarding to the transparent conducting film described in FIG. 4. As mentioned previously, the optical filter 40 is the absorption type narrow band pass filter.

Referring to FIG. 5A, the plot 50A is illustrated. The plot 50A compares the refractive indices of the transparent conducting film with and without oxygen flow during fabrication. During the fabrication without oxygen flow, an oxygen vacancy is introduced in the process chamber by adjusting the argon to oxygen ratio during deposition. This may lead to the formation of the transparent conducting oxide of a non-stoichiometric compound. The oxygen vacancy may produce free electron, and thus it is one method that generates the plasmonic feature for the transparent conducting film. Due to the plasmonic feature or the electric wave feature, free electrons may interact with each other, allowing the incident light to be more effectively absorbed. It can also be noticed that as the optical wavelength increases beyond approximately 800 nm, the refractive index of the transparent conducting film without oxygen flow decreases significantly more than the refractive index of the transparent conducting film with oxygen flow. The plasmonic feature of the transparent conducting film may create a larger difference between the refractive indices to enhance the interference. For example, the refractive index of the plasmonic transparent conducting film is less than 1.6 in the wavelength range between 1400 nm and 1600 nm. Even though the optical filter 40 is mainly absorption type, the optical filter 40 may still exhibit a slight interference feature that can assist in suppressing the unwanted wavelength.

Referring to FIG. 5B, the plot 50B is illustrated. The plot 50B compares the extinction coefficient of the transparent conducting film with and without oxygen flow during fabrication. During the fabrication without oxygen flow, the oxygen vacancy is introduced in the process chamber, leading to the formation of the transparent conducting oxide of the non-stoichiometric compound. The oxygen vacancy is one method that generates the plasmonic feature for the transparent conducting film. It can also be noticed that as the optical wavelength increases beyond approximately 1000 nm, the extinction coefficient of the transparent conducting film without oxygen flow increases significantly more than the extinction coefficient of the transparent conducting film with oxygen flow. For example, the extinction coefficient of the plasmonic transparent conducting film is greater than 0.01 in the wavelength range between 1400 nm and 1600 nm, greater than 0.05 in the wavelength range between 1400 nm and 1600 nm, or greater than 0.1 in the wavelength range between 1400 nm and 1600 nm. It should be appreciated that the narrow band gap materials typically has larger extinction coefficient only at short wavelength. The plasmonic feature of the transparent conducting film exhibits a relatively larger extinction coefficient at long wavelength. This allows the narrow band gap materials and the plasmonic transparent conducting film to be complementary with each other.

Referring to FIG. 5C, the plot 50C is illustrated. The plot 50C compares the optical constants (for example, the refractive index and the extinction coefficient) of indium tin oxide at different settings of the oxygen partial pressure during fabrication. In order to introduce the oxygen vacancy in the process chamber during the fabrication of indium tin oxide, the oxygen partial pressure should be maintained between 0.1 Pa and 30 Pa. If the oxygen partial pressure exceeds beyond 30 Pa, the oxygen composition in the process chamber may be too large to create any oxygen vacancy. In other words, the oxygen partial pressure of 30 Pa is the maximum tolerance of partial pressure settings. In the wavelength range between 800 nm and 1400 nm, the refractive index of indium tin oxide decreases in the order of 30 Pa, 10 Pa, 1 Pa, and 0.1 Pa. In the wavelength range between 1000 nm and 1600 nm, the extinction coefficient of indium tin oxide increases in the order of 30 Pa, 10 Pa, 1 Pa, and 0.1 Pa. The optical constants illustrated in plot 50C enable indium tin oxide to be applied in the optical filter 40 (such as the narrow band pass filter) at the wavelength of 940 nm.

According to a specific embodiment of the present disclosure, the indium tin oxide target inside the process chamber was a ceramic pellet with the In₂O₃:SnO₂ composition of 93%:7% by weight. Before the deposition of indium tin oxide, the background pressure of the process chamber is evacuated below 5×10⁻⁴ Pa. During the deposition of indium tin oxide, the indium tin oxide target and the substrate 100 are maintained at a distance of 5.5 cm. The temperature of the substrate 100 is kept at 300° C. inside the process chamber. Under these process conditions, the oxygen partial pressures of 0.1 Pa, 1 Pa, 10 Pa, and 30 Pa are experimented. At the wavelength of 1200 nm, the refractive indices of indium tin oxide are 0.8, 1.1, 1.3, and 1.4 under the oxygen partial pressure of 0.1 Pa, 1 Pa, 10 Pa, and 30 Pa, respectively. Also at the wavelength of 1200 nm, the extinction coefficients of indium tin oxide are 0.23, 0.1, 0.08, and 0.006 under the oxygen partial pressure of 0.1 Pa, 1 Pa, 10 Pa, and 30 Pa, respectively.

The high carrier concentration of the plasmonic transparent conducting film may be contributed by the intrinsic defects (such as the oxygen vacancies). In such materials, oxygen stoichiometry is a crucial factor in tuning the initial carrier concentrations, since the oxygen vacancies are electron donors. Increasing the oxygen concentration may decrease the oxygen vacancies, thus the carrier concentration may decrease.

In addition to adjusting the oxygen partial pressures, the optical constants (for example, the refractive index and the extinction coefficient) may also vary by fine-tuning the carrier concentrations in the appliance of an electric field. The plasma frequency of the plasmonic transparent conducting film can be calculated using the following equation:

$${ω}_{P}^{2} = \frac{{N}_{0} {e}^{2}}{{ε}_{0} {m}^{*}} \qquad ( 6 )$$

In equation (6), ω_{P} is the plasma frequency, N₀ is the bulk free carrier concentration, e is the electric charge, m* is the effective mass of electron, and ε₀ is the permittivity of free space. The presence of the oxygen flow may decrease the bulk free carrier concentration, which in turn lowers the plasma frequency, and the refractive index may remain large. In addition, the refractive index and the extinction coefficient may be fitted through the Drude-Lorentz model using the following equation:

$$ε ( ω ) = {ε}_{b} - \frac{{ω}_{P}^{2}}{{ω}^{2} + {γ}^{2}} + i \frac{{ω}_{P}^{2} γ}{( {ω}^{2} + {γ}^{2} ) ω} \qquad ( 7 )$$

In equation (7), ε_{b} is the background permittivity, ω is the angular frequency, and γ is the Drude relaxation rate. The Drude theory can describe how the conduction electrons interact with the electromagnetic filed, because the conduction electrons have a near continuum of available states.

It can be observed that inducing free carrier concentration is another method that generates the plasmonic feature for the transparent conducting film. For example, indium (III) oxide may be doped with tin (Sn). In comparison with In³⁺, Sn⁴⁺ has one additional electron donor. When the electron donor of the doped Sn⁴⁺ is matched with the electron acceptor of indium (III) oxide, free carrier concentration may be increased. The doping-induced free carriers may result in the Burstein-Moss effect, in which the band gap energy changes, and the locations of the cutbands (such as the short wavelength or the long wavelength) may be shifted.

Referring to FIG. 5D, the plot 50D is illustrated. The plot 50D compares the optical constants of two different transparent conducting films. The optical constants illustrated in the plot 50D enable both transparent conducting films to be applied in the narrow band pass filter at the wavelength of 1310 nm or at the wavelength of 1550 nm. Even though the transparent conducting films are highly transparent across the wavelength of visible light, the transparent conducting films are nonetheless conductive, which can absorb the wavelength of infrared.

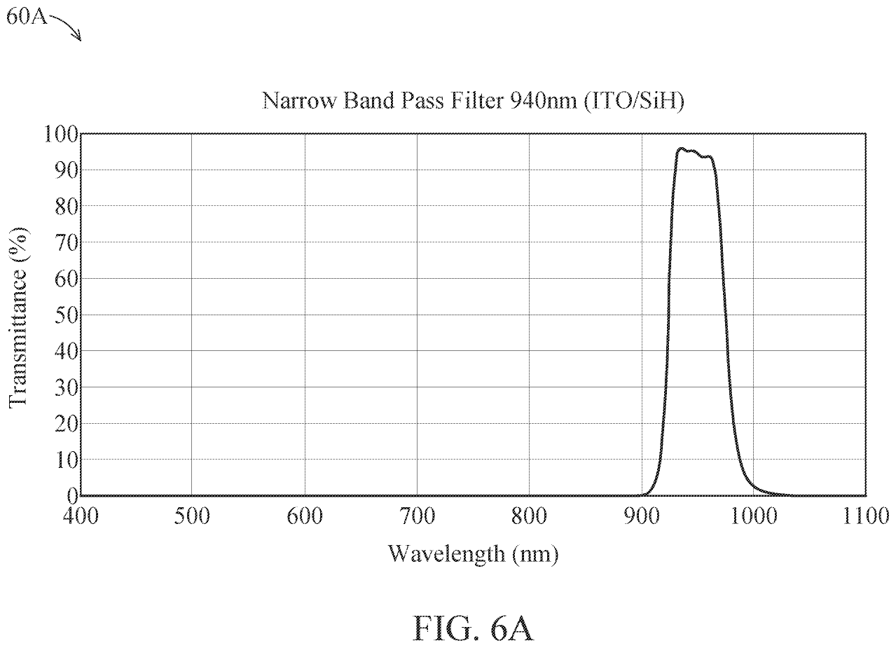

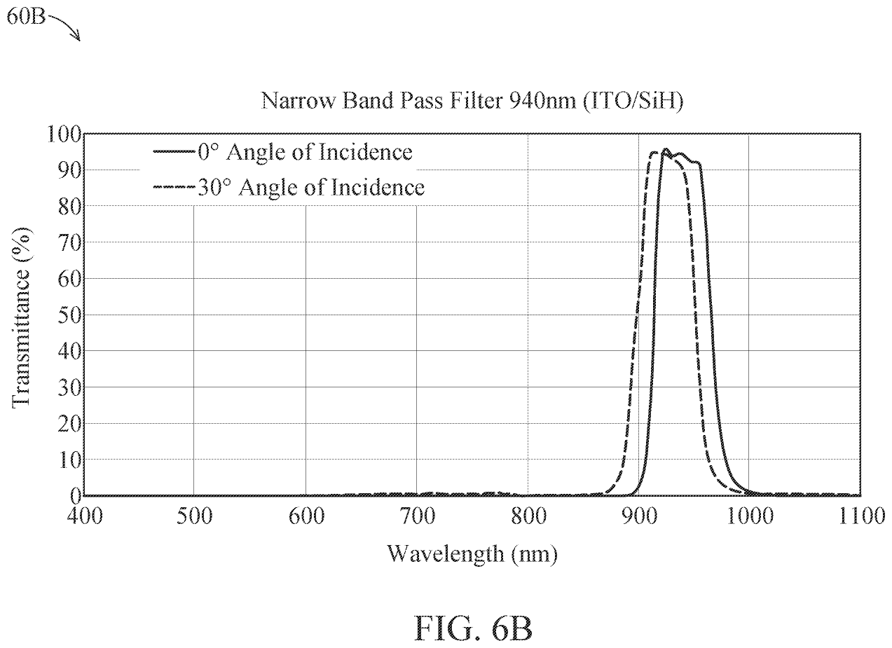

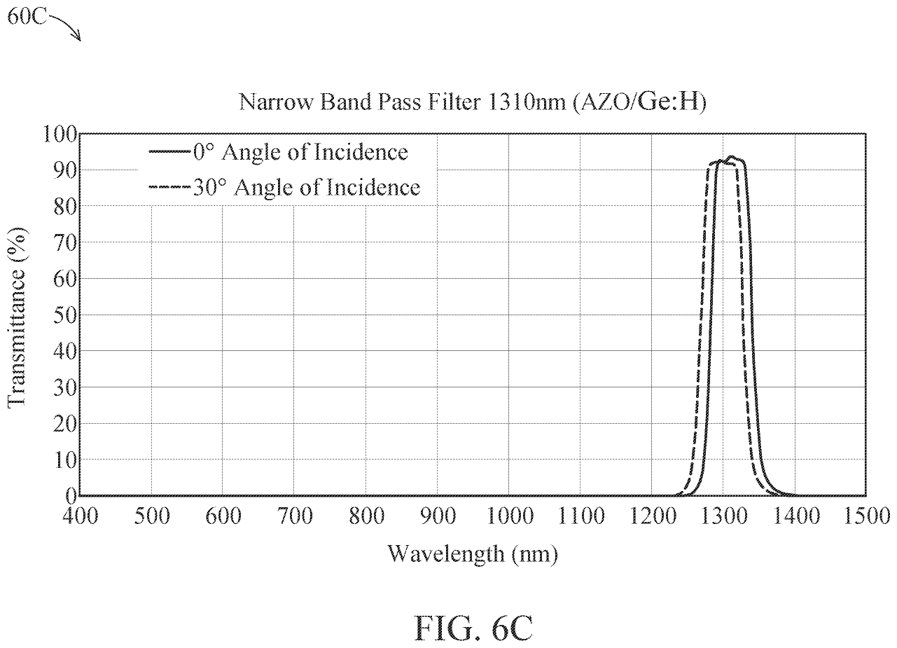

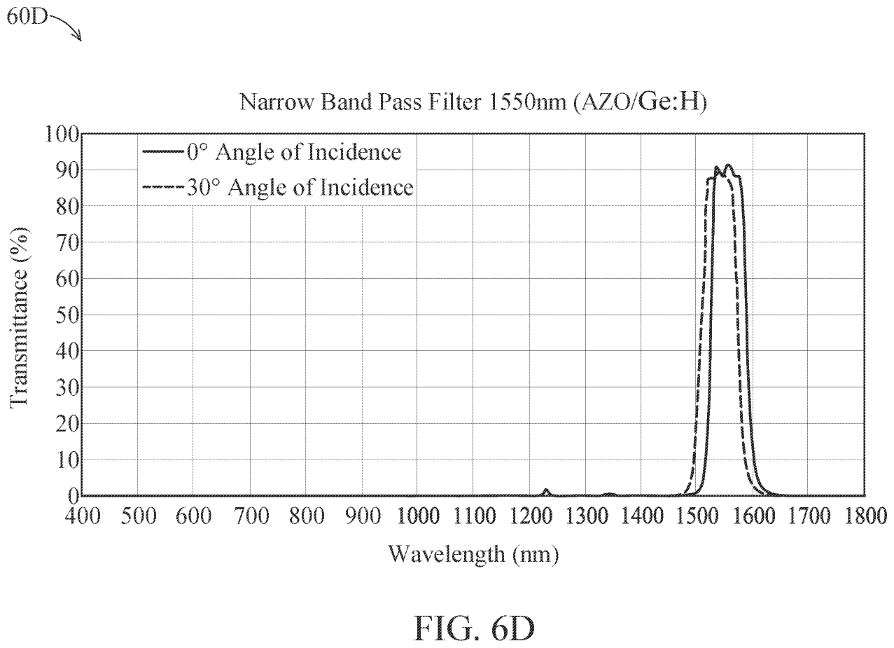

FIGS. 6A-6D are plots 60A-60D of the optical filter 40 with various characteristics, according to some embodiments of the present disclosure. The plots 60A-60D are based on the cross-sectional view shown in FIG. 4. As mentioned previously, the optical filter 40 is mainly the absorption type narrow band pass filter. Specifically, the high refractive index layers and the low refractive index layers are made of silicon hydride and the plasmonic transparent conducting oxide, respectively.

Referring to FIG. 6A, the plot 60A is illustrated. The plot 60A describes the transmittance of the optical filter 40 (for example, the narrow band pass filter at the wavelength of 940 nm). In the present embodiment, the transparent conducting oxide is indium tin oxide. The details of the filtering stack 110 of the optical filter 40 at the wavelength of 940 nm are summarized in Table 2.

TABLE 2

| | | |
|---|---|---|
| Layer | Material | Thickness |

Air

| | | | |
|---|---|---|---|
| 1 | silicon hydride (SiH) | 85.47 | nm |
| 2 | indium tin oxide (ITO) | 30.28 | nm |
| 3 | silicon hydride (SiH) | 175.63 | nm |
| 4 | indium tin oxide (ITO) | 119.10 | nm |
| 5 | silicon hydride (SiH) | 71.23 | nm |
| 6 | indium tin oxide (ITO) | 122.13 | nm |
| 7 | silicon hydride (SiH) | 295.32 | nm |
| 8 | indium tin oxide (ITO) | 88.35 | nm |
| 9 | silicon hydride (SiH) | 217.78 | nm |
| 10 | indium tin oxide (ITO) | 124.11 | nm |
| 11 | silicon hydride (SiH) | 297.55 | nm |
| 12 | indium tin oxide (ITO) | 68.11 | nm |
| 13 | silicon hydride (SiH) | 57.95 | nm |
| 14 | indium tin oxide (ITO) | 23.76 | nm |
| 15 | silicon hydride (SiH) | 18.23 | nm |

Substrate (glass)

| | | |
|---|---|---|
| Total | 1795.00 | nm |

As shown in Table 2, the thickness of the filtering stack 110 is 1795 nm, which is nearly 1.8 μm. It should be appreciated that the layers in the filtering stack 110 are listed from top to bottom. For example, layer 1 is the topmost layer, in which the upper surface thereof is exposed to ambient air. In contrast, layer 15 is the bottommost layer that is in contact with the substrate 100. In comparison with Table 1, the thickness of the filtering stack 110 can be reduced from 3 μm to 1.8 μm. Despite the reduced thickness of the filtering stack 110, the unwanted wavelengths can still be effectively suppressed. In general, when the passband is in the wavelength range between 800 nm and 1000 nm, the thickness of the filtering stack 110 is less than 2 μm. Therefore, the absorption type narrow band pass filter having plasmonic transparent conducting film may consume a lower manufacturing cost, and the device scaling may be more flexible. Furthermore, the cycle time to prepare the optical filter 40 with such filtering stack 110 decreases, thus the wafer per hour (WPH) of the production line may be improved. Since the filtering stack 110 has a relatively low thickness, the overall stress would decrease, resulting in fewer structural defects.

Referring to FIG. 6B, the plot 60B is illustrated. The plot 60B compares the angles of incidence of the incident light at 0° and at 30°. When the incident light is inclined from 0° to 30°, the passband of the narrow band pass filter at the wavelength of 940 nm may be blue shifted by approximately 14 nm. In other words, a difference between the central wavelength of the passband of the incident light at the angle of incidence of 0° and the central wavelength of the passband of the incident light at the angle of incidence of 30° is approximately 14 nm. When the angle of incidence changes from 0° to 30°, the major shift occurred in the region of the transmittance less than 50%. In comparison with FIG. 2D, the passband shift of the narrow band pass filter at the wavelength of 940 nm can be reduced from 22 nm to 14 nm. It should be appreciated that for the interference type narrow band pass filter, the constructive interference can be more significantly affected by the angle of incidence of the incident light. The application of the absorption type narrow band pass filter may alleviate the drastic passband shift in the event of changing the angle of incidence of the incident light.

Referring to FIG. 6C, the plot 60C is illustrated. The plot 60C describes the transmittance of the optical filter 40 (for example, the narrow band pass filter at the wavelength of 1310 nm). Moreover, the plot 60C also compares the angles of incidence of the incident light at 0° and at 30°. In the present embodiment, the plasmonic transparent conducting oxide is aluminum-doped zinc oxide. The details of the filtering stack 110 of the narrow band pass filter at the wavelength of 1310 nm are summarized in Table 3.

TABLE 3

| | | |
|---|---|---|
| Layer | Material | Thickness |

Air

| | | | |
|---|---|---|---|
| 1 | germanium hydride (GeH) | 90.78 | nm |
| 2 | aluminum-doped zinc oxide (AZO) | 24.32 | nm |
| 3 | germanium hydride (GeH) | 240.59 | nm |
| 4 | aluminum-doped zinc oxide (AZO) | 48.05 | nm |
| 5 | germanium hydride (GeH) | 86.31 | nm |
| 6 | aluminum-doped zinc oxide (AZO) | 133.00 | nm |
| 7 | germanium hydride (GeH) | 98.79 | nm |
| 8 | aluminum-doped zinc oxide (AZO) | 78.52 | nm |
| 9 | germanium hydride (GeH) | 124.18 | nm |
| 10 | aluminum-doped zinc oxide (AZO) | 11.51 | nm |
| 11 | germanium hydride (GeH) | 364.45 | nm |
| 12 | aluminum-doped zinc oxide (AZO) | 154.38 | nm |
| 13 | germanium hydride (GeH) | 79.73 | nm |
| 14 | aluminum-doped zinc oxide (AZO) | 153.37 | nm |
| 15 | germanium hydride (GeH) | 302.08 | nm |
| 16 | aluminum-doped zinc oxide (AZO) | 10.02 | nm |
| 17 | germanium hydride (GeH) | 41.28 | nm |
| 18 | aluminum-doped zinc oxide (AZO) | 94.18 | nm |
| 19 | germanium hydride (GeH) | 53.95 | nm |

Substrate (glass)

| | | |
|---|---|---|
| Total | 2189.54 | nm |

As shown in Table 3, the thickness of the filtering stack 110 is 2189.54 nm, which is nearly 2.2 μm. It should be appreciated that the layers in the filtering stack 110 are listed from top to bottom. For example, layer 1 is the topmost layer, in which the upper surface thereof is exposed to ambient air. In contrast, layer 19 is the bottommost layer that is in contact with the substrate 100. In comparison with Table 2, the thickness of the filtering stack 110 is increased from 1.8 μm to 2.2 μm, due to the longer wavelength where the optical filter 40 is operating under. However, it should be appreciated that the thickness of the filtering stack 110 of the absorption type narrow band pass filter at the wavelength of 1310 nm is smaller than the thickness of the filtering stack 110 of the interference type narrow band pass filter at the wavelength of 1310 nm. Despite the reduced thickness of the filtering stack 110, the unwanted wavelengths can still be effectively suppressed. Therefore, the absorption type narrow band pass filter having plasmonic transparent conducting film may consume a lower manufacturing cost, and the device scaling may be more flexible. Furthermore, the cycle time to prepare the narrow band pass filter with such filtering stack 110 decreases, thus the wafer per hour (WPH) of the production line may be improved. Since the filtering stack 110 has a relatively low thickness, the overall stress would decrease, resulting in fewer structural defects.

Still referring to FIG. 6C, when the incident light is inclined from 0° to 30°, the passband of the optical filter 40 (for example, the narrow band pass filter at the wavelength of 1310 nm) may be blue shifted by approximately 12 nm. In other words, a difference between the central wavelength of the passband of the incident light at the angle of incidence of 0° and the central wavelength of the passband of the incident light at the angle of incidence of 30° is approximately 12 nm. When the angle of incidence changes form 0° to 30°, the major shift occurred in the region of the transmittance less than 50%. In comparison with FIG. 6B, the passband shift of the optical filter 40 at the wavelength of 1310 nm is not much different from the passband shift of the optical filter 40 at the wavelength of 940 nm. It should be appreciated that for the interference type narrow band pass filter, the constructive interference can be more significantly affected by the angle of incidence of the incident light. Therefore, the passband shift of the absorption type narrow band pass filter at the wavelength of 1310 nm is lower than the passband shift of the interference type narrow band pass filter at the wavelength of 1310 nm.

Referring to FIG. 6D, the plot 60D is illustrated. The plot 60D describes the transmittance of the optical filter 40 (for example, the narrow band pass filter at the wavelength of 1550 nm). Moreover, the plot 60D also compares the angles of incidence of the incident light at 0° and at 30°. In the present embodiment, the plasmonic transparent conducting oxide is aluminum-doped zinc oxide. The details of the filtering stack 110 of the optical filter 40 at the wavelength of 1550 nm are summarized in Table 4.

TABLE 4

| | | |
|---|---|---|
| Layer | Material | Thickness |

Air

| | | | |
|---|---|---|---|
| 1 | germanium hydride (GeH) | 94.59 | nm |
| 2 | aluminum-doped zinc oxide (AZO) | 101.70 | nm |
| 3 | germanium hydride (GeH) | 97.50 | nm |
| 4 | aluminum-doped zinc oxide (AZO) | 42.85 | nm |
| 5 | germanium hydride (GeH) | 99.29 | nm |
| 6 | aluminum-doped zinc oxide (AZO) | 130.84 | nm |
| 7 | germanium hydride (GeH) | 95.65 | nm |
| 8 | aluminum-doped zinc oxide (AZO) | 202.70 | nm |
| 9 | germanium hydride (GeH) | 97.65 | nm |
| 10 | aluminum-doped zinc oxide (AZO) | 143.58 | nm |
| 11 | germanium hydride (GeH) | 278.94 | nm |
| 12 | aluminum-doped zinc oxide (AZO) | 13.80 | nm |
| 13 | germanium hydride (GeH) | 142.79 | nm |
| 14 | aluminum-doped zinc oxide (AZO) | 99.28 | nm |
| 15 | germanium hydride (GeH) | 100.09 | nm |
| 16 | aluminum-doped zinc oxide (AZO) | 108.12 | nm |
| 17 | germanium hydride (GeH) | 110.35 | nm |
| 18 | aluminum-doped zinc oxide (AZO) | 115.09 | nm |
| 19 | germanium hydride (GeH) | 112.13 | nm |
| 20 | aluminum-doped zinc oxide (AZO) | 98.51 | nm |
| 21 | germanium hydride (GeH) | 103.61 | nm |
| 22 | aluminum-doped zinc oxide (AZO) | 65.12 | nm |
| 23 | germanium hydride (GeH) | 119.16 | nm |
| 24 | aluminum-doped zinc oxide (AZO) | 35.42 | nm |
| 25 | germanium hydride (GeH) | 123.33 | nm |
| 26 | aluminum-doped zinc oxide (AZO) | 105.55 | nm |
| 27 | germanium hydride (GeH) | 88.81 | nm |

Substrate (glass)

| | | |
|---|---|---|
| Total | 2926.45 | nm |

As shown in Table 4, the thickness of the filtering stack 110 is 2926.45 nm, which is nearly 3 μm. It should be appreciated that the layers in the filtering stack 110 are listed from top to bottom. For example, layer 1 is the topmost layer, in which the upper surface thereof is exposed to ambient air. In contrast, layer 27 is the bottommost layer that is in contact with the substrate 100. In comparison with Table 3, the thickness of the filtering stack 110 is increased from 2.2 μm to 3 μm, due to the longer wavelength where the optical filter 40 is operating under. However, it should be appreciated that the thickness of the filtering stack 110 of the absorption type narrow band pass filter at the wavelength of 1550 nm is smaller than the thickness of the filtering stack 110 of the interference type narrow band pass filter at the wavelength of 1550 nm. Despite the reduced thickness of the filtering stack 110, the unwanted wavelength can still be effectively suppressed. In general, when the passband is in the wavelength range between 1200 nm and 1700 nm, the thickness of the filtering stack 110 is less than 3.5 μm. Therefore, the absorption type narrow band pass filter having plasmonic transparent conducting film may consume a lower manufacturing cost, and the device scaling may be more flexible. Furthermore, the cycle time to prepare the narrow band pass filter with such filtering stack 110 decreases, thus the wafer per hour (WPH) of the production line may be improved. Since the filtering stack 110 has a relatively low thickness, the overall stress would decrease, resulting in fewer structural defects.

Still referring to FIG. 6D, when the incident light is inclined from 0° to 30°, the passband of the optical filter 40 (for example, the narrow band pass filter at the wavelength of 1550 nm) may be blue shifted by approximately 16 nm. In other words, a difference between the central wavelength of the passband of the incident light at the angle of incidence of 0° and the central wavelength of the passband of the incident light at the angle of incidence of 30° is approximately 16 nm. When the angle of incidence changes from 0° to 30°, the major shift occurred in the region of the transmittance less than 50%. In comparison with FIG. 6B or FIG. 6C, the passband shift of the optical filter 40 at the wavelength of 1550 nm is not much different from the passband shift of the optical filter 40 at the wavelength of 940 nm or at the wavelength of 1310 nm. In general, a difference between the central wavelength of the passband of the incident light at the angle of incidence of 0° and the central wavelength of the passband of the incident light at the angle of incidence of 30° is less than 20 nm. It should be appreciated that for the interference type narrow band pass filter, the constructive interference can be more significantly affected by the angle of incidence of the incident light. Therefore, the passband shift of the absorption type narrow band pass filter at the wavelength of 1550 nm is lower than the passband shift of the interference type narrow band pass filter at the wavelength of 1550 nm.

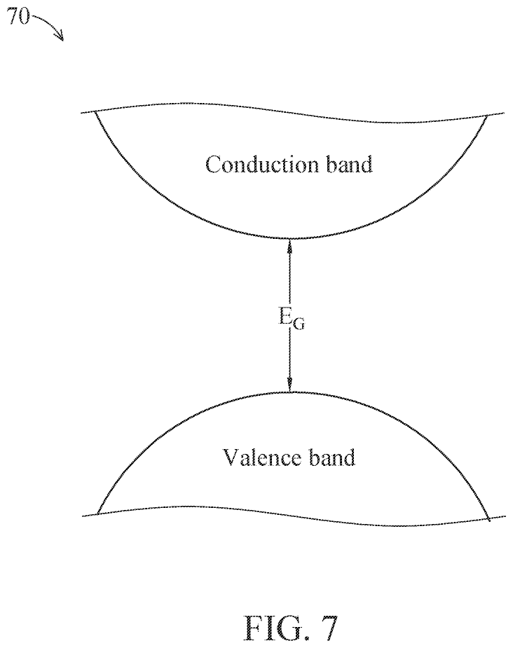

FIG. 7 is a schematic diagram 70 of band gap energy E_{G}, according to some embodiments of the present disclosure. For semiconductor or insulator, the valence band and the conduction band are separated by the band gap energy E_{G}. The light can be absorbed when its optical energy is equal to or greater than the band gap energy E_{G} of the semiconductor or the insulator. The band gap energy E_{G} sets the minimum wavelength for which the material is transparent. Using the band gap energy E_{G}, the desired material may be selected, and the unwanted transmittance may be filtered before the near infrared wavelength.

The band gap energy E_{G} can be calculated using the following equation:

$${E}_{G} = \frac{h \times c}{λ} \qquad ( 8 )$$

In equation (8), h is the Planck's constant (which is 6.626×10⁻³⁴ J-sec), c is the speed of light (which is 3×10⁸ m/sec), and λ is the wavelength (or the minimum wavelength). Based on eauation (8), the wavelength can be derived from the following equations:

$$λ = \frac{h \times c}{{E}_{G}} = \frac{( 6.626 \times {10}^{- 34} J \cdot sec ) \times ( 3 \times {10}^{8} m / sec )}{{E}_{G} ( eV ) \times \frac{1.6 \times {10}^{- 19} J}{1 eV}} = \frac{1240 \times {10}^{- 9}}{{E}_{G}} m \qquad ( 9 )$$

$$λ = \frac{1240}{{E}_{G}} nm$$

It is worth noted that 1 electronvolt (eV) equals 1.6×10⁻¹⁹ Joules (J). In order to divide the Planck's constant by the band gap energy E_{G}, the unit of the band gap energy E_{G} must first be converted from electronvolt to joules. Since 1 meter equals 1×10⁻⁹ nanometer, the wavelength (in nanometer) is simply 1240 divided by the band gap energy E_{G}. It can be observed that the wavelength and the band gap energy E_{G} are inversely proportional with each other.

Electrons travelling from ground state to excited state means the material is having band gap, which can thus be determine by absorption wavelength. For the narrow band pass filter at the wavelength of 940 nm, the narrow band gap material has the band gap energy E_{G} of 1.37 eV, and the absorption wavelength may be calculated to be 905 nm. For the narrow band pass filter at the wavelength of 1310 nm or at the wavelength of 1550 nm, the narrow band gap material has the band gap energy E_{G} of 1 eV, and the absorption wavelength may be calculated to be 1240 nm. At longer wavelength (for example, of short wave infrared), the narrow band gap material may have the band gap energy E_{G} less than 1 eV, and the absorption wavelength may be above 1240 nnm.

FIG. 8 is a cross-sectional view of an optical filter 80, according to other embodiments of the present disclosure. In the present embodiment, the optical filter 80 may be an organic photo diode (OPD) incorporated with the filtering stack 110. The features of the substrate 100 and the filtering stack 110 are similar to those illustrated in FIG. 4, and the details are not described again herein to avoid repetition.

Referring to FIG. 8, an organic photoconductive film (OPF) 108 may be disposed below the filtering stack 110. The function of the organic photoconductive film 108 is to convert photons to electrons. The thickness of the organic photoconductive film 108 may be between 0.05 μm and 0.70 μm. Materials of the organic photoconductive film 108 may include small molecules (such as fluorene dithiophene (FDT), copper phthalocyanine (CuPc), lead phthalocyanine (PbPc), chloroaluminum phthalocyanine (AlClPc)), fullerene (such as C70, C60), the like, or a combination thereof. The organic photoconductive film 108 may be formed by any suitable deposition process mentioned above.

Still referring to FIG. 8, an electron transport layer (ETL) 106A and a hole transport layer (HTL) 106B may be respectively formed below and above the organic photoconductive film 108. In some embodiments, the electron transport layer 106A may be located vertically between the substrate 100 and the organic photoconductive film 108, while the hole transport layer 106B may be located vertically between the filtering stack 110 and the organic photoconductive film 108. The electron transport layer 106A and the hole transport layer 106B may be considered as the buffer layers for anode connection and cathode connection, respectively. The thickness of the electron transport layer 106A or the hole transport layer 106B may be between 10 nm and 100 nm. Materials of the electron transport layer 106A and the hole transport layer 106B may include polymers (such as polybis(thienyl)thienodia-thiazolethiophene (PDDTT), poly[2,3-bis(4-(2-ethylhexyloxy)phenyl)-5,7-di(thiophen-2-yl)thieno[3,4-b]pyrazine] (PDTTP), poly {2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl} (PDPP3T), thienyl-diketopyrrolopyrrole-thieno-thiophene (PDPPTTT), poly{4,8-bis[5-(2-ethylhexyl)thiophen-2-yl]benzo[1,2-b:4,5-b′]-dithiophene-2,6-diyl-alt-3-fluoro-2-[(2-ethylhexyl)carbonyl]-thieno[3,4-b]thiophene-4,6-diyl} (PTB7-Th)), any suitable organic materials, the like, or a combination thereof. The electron transport layer 106A and the hole transport layer 106B may be formed by any suitable deposition process mentioned above.

Referring to FIG. 8, a bottom electrode 104 may be disposed below the electron transport layer 106A. The bottom electrode 104 and the filtering stack 110 may respectively serve as the anode contact and the cathode contact. It should be appreciated that the filtering stack 110 may act as a top electrode of the conventional organic photo diode. The thickness of the bottom electrode 104 may depend on the design of the substrate 100. Materials of the bottom electrode 104 may include amorphous silicon, polysilicon, poly-SiGe, metal nitride (such as titanium nitride (TiN), tantalum nitride (TaN), tungsten nitride (WN), titanium aluminum nitride (TiAlN), or the like), metal silicide (such as nickel silicide (NiSi), cobalt silicide (CoSi), tantalum silicon nitride (TaSiN), or the like), metal carbide (such as tantalum carbide (TaC), tantalum carbonitride (TaCN), or the like), metal oxide, or metals. Metals may include cobalt (Co), ruthenium (Ru), aluminum (Al), tungsten (W), copper (Cu), titanium (Ti), tantalum (Ta), silver (Ag), gold (Au), platinum (Pt), nickel (Ni), the like, a combination thereof, or a multiple layer thereof. The bottom electrode 104 may be formed by physical vapor deposition, atomic layer deposition, plating, sputtering, the like, or a combination thereof.

Still referring to FIG. 8, a via structure 109 may be disposed through the filtering stack 110, the hole transport layer 106B, the electron transport layer 106A, the organic photoconductive film 108, and may be in contact with the bottom electrode 104. According to some embodiments of the present disclosure, the filtering stack 110 and the bottom electrode 104 may be electrically coupled through the via structure 109. Moreover, the via structure 109 may also function as a power switch during the operation of the optical filter 80. Materials and formation of the via structure 109 may be similar to those of the bottom electrode 104, and the details are not described again herein to avoid repetition.

Referring to FIG. 8, a plurality of circuit portions 102 may be electrically connected to the bottom electrode 104. In some embodiments, the plurality of circuit portions 102 and the bottom electrode 104 are both embedded within the substrate 100. The function of the plurality of circuit portions 102 is to connect to circuit system and to form charge storage region. The plurality of circuit portions 102 may include any suitable insulating and conductive materials mentioned above. For example, the plurality of circuit portions 102 may be a laminated structure having the insulating layers and the conductive layers that are alternately arranged.

Still referring to FIG. 8, a micro-lens material layer 120 may be disposed on the filtering stack 110. The refractive index of the micro-lens material layer 120 is between 1.2 and 2.2. In some embodiments, the micro-lens material layer 120 may include a transparent material. Examples of the transparent material may include glass, epoxy resin, silicone resin, polyurethane, any other applicable material, or a combination thereof, but the present disclosure is not limited thereto. According to some embodiments of the present disclosure, a plurality of micro-lenses 122 may be disposed on the micro-lens material layer 120. In some embodiments, the plurality of micro-lenses 122 may be formed by patterning the top portion of the micro-lens material layer 120 to correspond to the plurality of circuit portions 102, respectively. Because the plurality of micro-lenses 122 are formed from the micro-lens material layer 120, the plurality of micro-lenses 122 and the micro-lens material layer 120 share the same material.

The present disclosure incorporates the plasmonic transparent conducting film into the filtering stack of the optical filter. When the optical filter is designed into the narrow band pass filter, the plasmonic transparent conducting film may more effectively absorb the unwanted wavelengths (such as longer wavelengths), and only the desired wavelength may be transmitted. Conventionally, the narrow band pass filter utilizes the difference between refractive indices to create interference for the suppression of unwanted wavelengths. By implementing the plasmonic transparent conducting film with non-stoichiometric compounds in the filtering stack, the unwanted wavelengths may be absorbed, instead of being interfered. Unlike the conventional interference type narrow band pass filters, the filtering stack of the absorption type narrow band pass filter can be designed into lower dimension. As a result, the cycle time to prepare the narrow band pass filter with such filtering stack decreases, thus the wafer per hour of the production line may be improved. Since the filtering stack has a relatively low thickness, the overall stress would decrease, resulting in fewer structural defects.

The foregoing outlines features of several embodiments so that those skilled in the art will better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An optical filter, comprising:
a substrate;
a filtering stack disposed on the substrate, comprising:
first layers; and
second layers alternately arranged with the first layers, wherein the second layers comprise a plasmonic transparent conducting film (TCF), wherein the plasmonic transparent conducting film is made of non-stoichiometric compounds.

2. The optical filter of claim 1, wherein the optical filter has a passband partially overlapping with a wavelength range between 800 nm and 1700 nm.

3. The optical filter of claim 1, wherein from top to bottom of the filtering stack, the first layers and the second layers are arranged in one of:
a (T−N)^{L}−T order,
a (T−N)^{L} order,
an N−(T−N)^{L} order, or
an (N−T)^{L} order,
wherein N represents the first layers, T represents the second layers, and L represents the quantity of alternating the first layers and the second layers, wherein L is between 15 and 30.

4. The optical filter of claim 1, wherein the first layers comprise a narrow band gap material.

5. The optical filter of claim 4, wherein the narrow band gap material is transparent in a wavelength range of near infrared (NIR) or short wave infrared (SWIR).

6. The optical filter of claim 4, wherein the narrow band gap material comprises copper zinc tin sulfide (Cu₂ZnSnS₄, CZTS), copper strontium tin sulfide (Cu₂SrSnS₄, CSTS), copper indium gallium selenide (CuIn₁₋ₓGaₓSe₂, CIGS), amorphous silicon, silicon hydride (SiH), silicon germanium (SiGe), germanium hydride (GeH), germanium peroxide (GeOH), silicon tin (SiSn), germanium silicon tin (GeSiSn), or germanium tin (GeSn).

7. The optical filter of claim 4, wherein an extinction coefficient of the narrow band gap material is greater than 0.01 in a wavelength range between 300 nm and 600 nm.

8. The optical filter of claim 7, wherein the extinction coefficient of the narrow band gap material is greater than 0.05 in the wavelength range between 300 nm and 600 nm, or greater than 0.1 in the wavelength range between 300 nm and 600 nm.

9. The optical filter of claim 1, wherein the plasmonic transparent conducting film is absorptive in a wavelength range of near infrared or short wave infrared.

10. The optical filter of claim 1, wherein the plasmonic transparent conducting film is a transparent conducting oxide (TCO), the transparent conducting oxide comprises indium (III) oxide (In₂O₃), zinc oxide (ZnO), indium (III) oxide-zinc oxide, aluminum-doped zinc oxide (AZO), gallium zinc oxide (GZO), indium tin oxide (ITO), indium zinc oxide (IZO), indium tungsten oxide (IWO), magnesium-doped zinc oxide (MZO), antimony tin oxide (ATO), fluorine-doped tin oxide (FTO), indium gallium tin oxide (IGTO), tin (IV) oxide (SnO₂), titanium-doped niobium oxide (TNO), titanium nitride (TiN), copper (I) oxide (Cu₂O), tantalum oxide (Ta₂Oₓ), gallium indium oxide (GaInOₓ), indium gallium zinc oxide (InGaZnO), zinc tin oxide (ZnₓSnO_{y}), zinc gallium oxide (ZnGaₓ O_{y}), gallium indium oxide (GaInOₓ), zinc indium oxide (Znₓ In_{y}O_{z}), vanadium oxide (VOₓ), or molybdenum oxide (MoOₓ).

11. The optical filter of claim 10, wherein the plasmonic transparent conducting film comprises indium (III) oxide doped with tin.

12. The optical filter of claim 1, wherein a refractive index of the plasmonic transparent conducting film is less than 1.6 in a wavelength range between 1600 nm and 1800 nm.

13. The optical filter of claim 12, wherein an extinction coefficient of the plasmonic transparent conducting film is greater than 0.01 in the wavelength range between 1600 nm and 1800 nm.

14. The optical filter of claim 13, wherein the extinction coefficient of the plasmonic transparent conducting film is greater than 0.05 in the wavelength range between 1600 nm and 1800 nm, or greater than 0.1 in the wavelength range between 1600 nm and 1800 nm.

15. The optical filter of claim 1, wherein a difference between a central wavelength of a first passband of an incident light at an angle of incidence of 0° and a central wavelength of a second passband of the incident light at an angle of incidence of 30° is less than 20 nm.

16. The optical filter of claim 2, wherein when the passband is in a wavelength range between 800 nm and 1000 nm, a thickness of the filtering stack is less than 2 μm.

17. The optical filter of claim 2, wherein when the passband is in a wavelength range between 1200 nm and 1700 nm, a thickness of the filtering stack is less than 3.5 μm.

18. The optical filter of claim 1, further comprising:
an organic photoconductive film (OPF) disposed below the filtering stack;
an electron transport layer (ETL) disposed vertically between the substrate and the organic photoconductive film; and
a hole transport layer (HTL) disposed vertically between the filtering stack and the organic photoconductive film.

19. The optical filter of claim 18, wherein a plurality of circuit portions and a bottom electrode are embedded in the substrate, and the bottom electrode electrically connects the plurality of circuit portions and the electron transport layer.

20. The optical filter of claim 19, wherein the filtering stack and the bottom electrode are electrically coupled through a via structure.
